(19) United States
(12) Patent Application Publication
(10) Pub. No.: US 2007/0284653 A1
(43) Pub. Date: Dec. 13, 2007

(54) Semiconductor device

(76) Inventors: Hiroaki Ueno, Osaka (JP); Manabu Yanagihara, Osaka (JP); Yasuhiro Uemoto, Shiga (JP); Tsuyoshi Tanaka, Osaka (JP)

Correspondence Address: MCDERMOTT WILL & EMERY LLP, 600 13TH STREET, NW, WASHINGTON, DC, 20005-3096, US

(21) Appl. No.: 11/785,801

(22) Filed: Apr. 20, 2007

(30) Foreign Application Priority Data
Jun. 8, 2006 (JP) 2006-160206

(51) Int. Cl. H01L 29/792

(52) U.S. Cl. 257/324

(57) ABSTRACT

A semiconductor device includes a first group III-V nitride semiconductor layer, a second group III-V nitride semiconductor layer having a larger band gap than the first group Ill-V nitride semiconductor layer and at least one ohmic electrode successively formed on a substrate. The ohmic electrode is formed so as to have a base portion penetrating the second group III-V nitride semiconductor layer and reaching a portion of the first group III-V nitride semiconductor layer disposed beneath a two-dimensional electron gas layer. An impurity doped layer is formed in portions of the first group III-V nitride semiconductor layer and the second group III-V nitride semiconductor layer in contact with the ohmic electrode.

### CROSS-REFERENCE TO RELATED APPLICATIONS

This application claims priority under 35 U.S.C. §119 on Patent Application No. 2006-160206 filed in Japan on Jun. 8, 2006, the entire contents of which are hereby incorporated by reference.

### BACKGROUND OF THE INVENTION

The present invention relates to a semiconductor device using a group III-V nitride semiconductor, and more particularly, it relates to a group III-V nitride semiconductor device including an ohmic electrode with small contact resistance.

A group III-V nitride semiconductor is a compound semiconductor that includes a compound of aluminum (Al), boron (B), gallium (Ga) or indium (In), and nitrogen (N) and is represented by a general formula of B_{w}AlₓGa_{y}In_{z}N (wherein w+x+y+z=1 and 0≦w, x, y, z≦1).

Group III-V nitride semiconductors have advantages such as a high breakdown voltage derived from a large band gap, high electron saturated velocity and high electron mobility and advantages such as a high electron concentration on heterojunction. Group III-V nitride semiconductors are being earnestly studied and developed for application to a power device, a high-speed device for millimeter wave band and the like. In particular, a heterojunction structure in which group III-V nitride semiconductor layers having different band gaps are stacked, or a quantum well structure or a superlattice structure in which a plurality of heterojunction structures are stacked is employed as a basic structure of a device utilizing a group Ill-V nitride semiconductor. This is because the modulation degree of an electron concentration in the device can be controlled using such a structure.

An example of a semiconductor device utilizing a group III-V nitride semiconductor and having a heterojunction structure is a heterojunction field effect transistor (HFET) (see, for example, Japanese Laid-Open Patent Publication No. 2002-16245).

An HFET includes an operation layer made of gallium nitride (GaN), a barrier layer made of undoped aluminum gallium nitride (AlGaN), and a source electrode, a drain electrode and a gate electrode formed on the barrier layer, all of which are successively formed on a substrate.

Since AlGaN has a larger band gap than GaN, electrons derived from a spontaneous polarization difference and a piezoelectric polarization difference between the AlGaN and the GaN, electrons derived from an n-type impurity doped in the barrier layer if necessary and electrons derived from other uncontrollable defects caused in the semiconductor layers are accumulated in a high concentration on a heterojunction interface between the operation layer and the barrier layer, resulting in forming a two-dimensional electron gas (2DEG) layer. The 2DEG layer works as a channel carrier of the field effect transistor.

Alternatively, when a cathode (ohmic) electrode and an anode electrode are formed on group III-V nitride semiconductor layers stacked so as to form a heterojunction interface therebetween, a Schottky barrier diode (SBD) in which a 2DEG layer works as a channel carrier of the diode is obtained (see, for example, Japanese Laid-Open Patent Publication No. 2004-31896).

In order to apply a semiconductor device using a group III-V nitride semiconductor to a power device or a high-speed device for millimeter wave band, it is necessary to reduce the contact resistance of an ohmic electrode portion so as to reduce the on resistance. In a conventional HFET or SBD, however, a source/drain electrode or a cathode electrode is formed on an undoped AlGaN layer. Therefore, the electrons should reach the 2DEG layer beyond the potential barrier of the undoped AlGaN layer, and hence, the contact resistance is high.

As a method for reducing the contact resistance, for example, a recess ohmic structure in which a recess is formed in an uppermost barrier layer, an ohmic contact layer is formed in the recess and an ohmic electrode is formed on the ohmic contact layer is known (see, for example, Japanese Laid-Open Patent Publication No. 2001-102565). Also, a method in which the contact resistance is reduced by introducing an impurity with a conducting property into a surface portion of a barrier layer is known (see, for example, Japanese Laid-Open Patent Publication Nos. 2004-56146 and 2004-111910).

In the conventional semiconductor device having the recess ohmic structure, however, a potential barrier still remains in the barrier layer. Also, there still remains a problem that the contact resistance cannot be sufficiently reduced because a semiconductor layer may be damaged through etching performed for forming the recess or the carrier concentration in the 2DEG layer may be lowered through the etching damage.

Furthermore, it is difficult to determine an etching end point in the formed recess, which makes the fabrication process for the semiconductor device complicated and disadvantageously lowers the yield.

### SUMMARY OF THE INVENTION

The present invention was devised to overcome the aforementioned conventional disadvantage and problem, and an object of the invention is realizing a semiconductor device using a group III-V nitride semiconductor and including an ohmic electrode with small contact resistance.

In order to achieve the object, the semiconductor device of this invention includes an ohmic electrode in direct contact with a two-dimensional electron gas layer.

Specifically, the semiconductor device of this invention includes a first group III-V nitride semiconductor layer formed above a substrate and having a two-dimensional electron gas layer; a second group III-V nitride semiconductor layer formed on the first group III-V nitride semiconductor layer and having a larger band gap than the first group III-V nitride semiconductor layer; at least one ohmic electrode formed to have a base portion penetrating the second group III-V nitride semiconductor layer and reaching a portion of the first group Ill-V nitride semiconductor layer disposed beneath the two-dimensional electron gas layer; and an impurity doped layer formed in portions of the first group Ill-V nitride semiconductor layer and the second group III-V nitride semiconductor layer in contact with the ohmic electrode, and doped with an impurity having conductivity.

In the semiconductor device of this invention, the ohmic electrode is in direct contact with the two-dimensional electron gas layer. In particular, the impurity doped layer doped with an impurity having conductivity is formed on the contact face between the electrode and the semiconductor layer, and therefore, the electrode and the two- dimensional electron gas layer are not in point or line contact but in plane contact. Accordingly, electrons can reach the two-dimensional electron gas layer without overpassing a potential barrier of the barrier layer, and hence, contact resistance can be largely reduced.

In the semiconductor device of this invention, the second group III-V nitride semiconductor layer preferably has a multilayered structure in which a plurality of group III-V nitride semiconductor layers are stacked.

In the semiconductor device of this invention, the ohmic electrode is preferably two in number spaced from each other, and a gate electrode is preferably formed above the second group Ill-V nitride semiconductor layer to be disposed between the two ohmic electrodes. Thus, a field effect transistor including an ohmic electrode with small contact resistance can be realized.

The semiconductor device of this invention preferably further includes a third group III-V nitride semiconductor layer formed on the second group Ill-V nitride semiconductor layer, and the ohmic electrode is preferably formed to have at least a portion thereof penetrating the third group Ill-V nitride semiconductor layer. Thus, the contact resistance can be largely reduced even when the semiconductor device includes a capping layer.

In this case, the third group III-V nitride semiconductor layer preferably has a multilayered structure in which a plurality of group III-V nitride semiconductor layers are stacked.

In this case, the ohmic electrode is preferably two in number spaced from each other, and a gate electrode is preferably formed above the second group III-V nitride semiconductor layer to be disposed between the two ohmic electrodes.

In this case, the third group III-V nitride semiconductor layer preferably has, in a region disposed between the two ohmic electrodes, a gate recess for exposing the second group III-V nitride semiconductor layer therein, and the gate electrode is preferably formed in the gate recess.

In this case, the semiconductor device preferably further includes a fourth group III-V nitride semiconductor layer having a p-type conductivity and formed between the gate electrode and the third group III-V nitride semiconductor layer, and the gate electrode is preferably in ohmic contact with the fourth group III-V nitride semiconductor layer.

The semiconductor device of this invention preferably further includes an anode electrode formed above the second group III-V nitride semiconductor layer in a position different from the ohmic electrode and in Schottky contact with the second group III-V nitride semiconductor layer. Thus, a Schottky barrier diode including a cathode electrode with small contact resistance can be realized.

In the semiconductor device of the invention, the ohmic electrode is preferably formed by filling an opening penetrating the second group III-V nitride semiconductor layer and reaching a portion of the first group III-V nitride semiconductor layer disposed beneath the two-dimensional electron gas layer, and a wall of the opening is preferably inclined to have a larger width in a higher portion thereof. Thus, the ohmic electrode can be easily formed by deposition and lift-off, so that the semiconductor device can attain high reliability.

In the semiconductor device of the invention, the impurity having the conductivity is preferably silicon.

In the semiconductor device of the invention, the base portion of the ohmic electrode is preferably formed down to a portion of the first group III-V nitride semiconductor layer deeper than the two-dimensional electron gas layer by 10 nm or more. Thus, the contact resistance can be definitely reduced. Also, since there is no need to strictly control the etching end point in forming the opening by the etching, the semiconductor device can be easily fabricated.

In the semiconductor device of the invention, the ohmic electrode preferably has an overhang portion overhanging a top face of the second group III-V nitride semiconductor layer, and the overhang portion preferably has a length of 1 μm or less. Thus, increase of the sheet resistance of the two-dimensional electron gas layer caused by the influence of the overhang portion can be avoided, and hence, increase of the contact resistance can be suppressed.

### BRIEF DESCRIPTION OF THE DRAWINGS

FIG. 1 is a cross-sectional view of a semiconductor device according to Embodiment 1 of the invention.

FIG. 2 is a cross-sectional view of an ohmic electrode portion of the semiconductor device of Embodiment 1.

FIG. 3 is a graph for showing the correlation between the length of an overhang portion of an ohmic electrode and contact resistance obtained in the semiconductor device of Embodiment 1.

FIG. 4 is a graph for showing current-voltage characteristics of the semiconductor device of Embodiment 1.

FIG. 5 is a cross-sectional view of a semiconductor device according to Embodiment 2 of the invention.

FIG. 6 is a graph for showing the correlation between the depth of an opening and a contact resistance ratio obtained in the semiconductor device of Embodiment 2.

FIG. 7 is a cross-sectional view of a semiconductor device according to Embodiment 3 of the invention.

FIG. 8 is a cross-sectional view of a semiconductor device according to Embodiment 4 of the invention.

FIG. 9 is a graph for showing a current-voltage characteristic of the semiconductor device of Embodiment 4.

### DETAILED DESCRIPTION OF THE INVENTION

### Embodiment 1

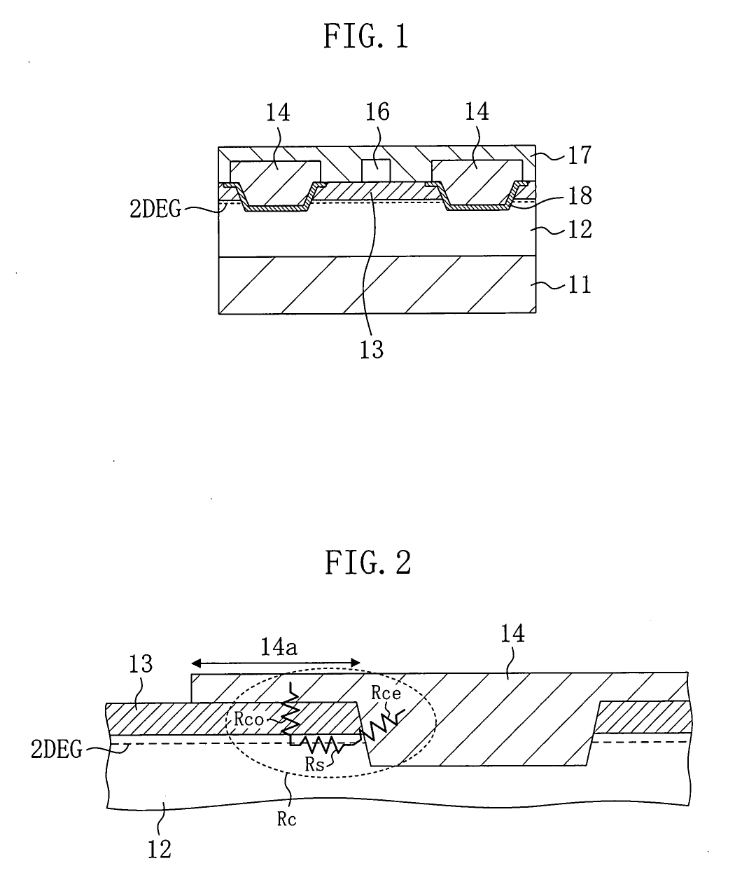

Embodiment 1 of the invention will now be described with reference to the accompanying drawings. FIG. 1 shows the cross-sectional structure of a semiconductor device according to this embodiment. As shown in FIG. 1, the semiconductor device of this embodiment is a heterojunction field effect transistor (HFET). An operation layer 12 made of undoped GaN and a barrier layer 13 made of undoped AlₓGa₍₁₋ₓ₎N (wherein 0<x≦1) having a larger band gap than GaN are stacked on a substrate 11. Since a heterojunction interface is formed between the operation layer 12 and the barrier layer 13, a two-dimensional electron gas (2DEG) layer is generated in the vicinity of the heterojunction interface.

A gate electrode 16 corresponding to a Schottky electrode is formed on the barrier layer 13, and ohmic electrodes 14 working as a source electrode and a drain electrode are formed on both sides of the gate electrode 16. A surface protection film 17 made of silicon nitride (SiN) is formed so as to cover the gate electrode 16 and the ohmic electrodes 14.

In the HFET of this embodiment, each ohmic electrode 14 is formed so as to have a base thereof penetrating the barrier layer 13 and reaching a portion of the operation layer 12 disposed beneath the 2DEG layer. Specifically, each ohmic electrode is formed by filling a conducting material in an opening formed so as to penetrate the barrier layer 13 and to trench the operation layer 12. The opening to be filled with the conducting material is formed to be deeper than the 2DEG layer and is preferably formed to be deeper than the 2DEG layer by 10 nm or more, so that the resultant ohmic electrode can attain low resistance. Also, as described below, when the opening is formed to be deeper than the 2DEG layer by 10 nm or more, the contact resistance is substantially constant, and hence, there is no need to strictly control the etching end point in forming the opening by the etching. Therefore, the semiconductor device can be easily fabricated.

Furthermore, an n-type impurity doped layer 18 doped with an n-type dopant of silicon or the like is formed in portions of the operation layer 12 and the barrier layer 13 in contact with the ohmic electrodes 14. Since the impurity doped layer 18 is thus formed in the portions of the operation layer 12 and the barrier layer 13 in contact with the ohmic electrodes 14, the contact resistance can be farther reduced. The concentration of silicon introduced into the impurity doped layer 18 is approximately 1×10¹⁹ cm⁻³.

Since the ohmic electrodes 14 are buried in the openings and the n-type dopant is introduced into the interfaces between the ohmic electrodes 14 and the operation layer 12 and the barrier layer 13 in this manner, the ohmic electrodes 14 can be in direct contact with the 2DEG layer in a large area, and hence, the contact resistance can be reduced. In order to reduce the contact resistance, each ohmic electrode 14 is ideally formed to have a width completely according with the width of the opening so as not to overhang the barrier layer 13.

FIG. 2 is an enlarged view of an ohmic electrode portion of the semiconductor device for showing resistance caused between the ohmic electrode 14 and the 2DEG layer. The contact resistance Rc of the ohmic electrode 14 depends upon the resistance Rce of a portion of the ohmic electrode 14 directly in contact with the 2DEG layer, the resistance Rco of a portion of the ohmic electrode 14 adjacent to the 2DEG layer with the barrier layer 13 sandwiched therebetween and the sheet resistance Rs of the 2DEG layer.

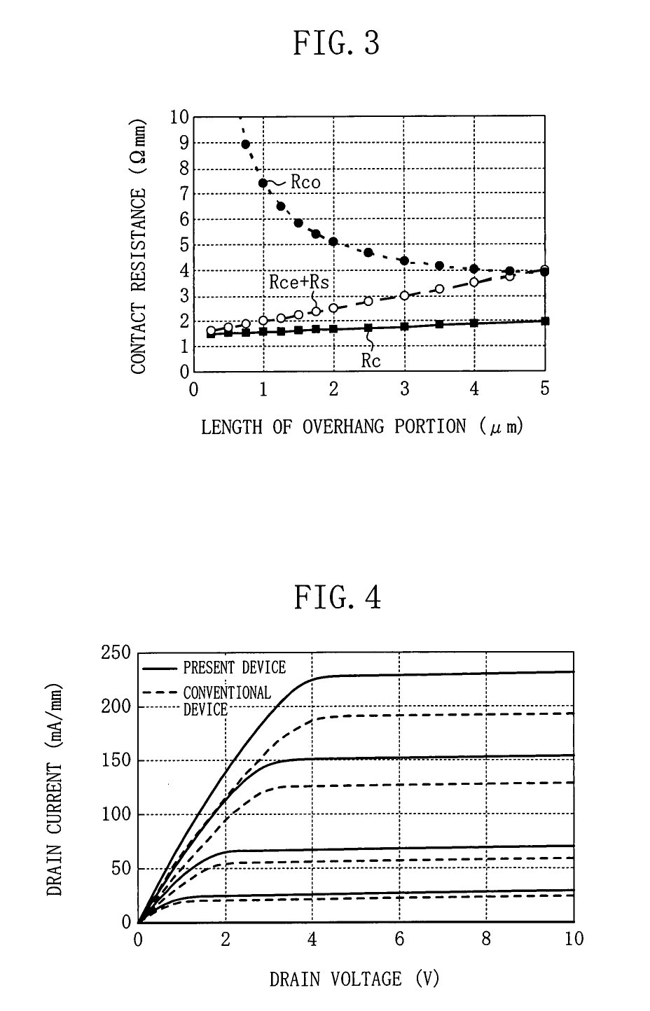

As shown in FIG. 3, when the length of an overhang portion 14a (shown in FIG. 2) of the ohmic electrode 14 overhanging the barrier layer 13 is large, the sheet resistance Rs of the 2DEG layer is unavoidably increased, which increases the total contact resistance Rc. Therefore, the length of the overhang portion 14a is preferably as small as possible. However, it is actually impossible to avoid the overhang portion 14a in view of process, and hence, the length is preferably 1 μm or less.

Moreover, the wall of the opening is preferably in an inclined shape. The ohmic electrode 14 is generally formed by a lift-off method in which a resist film is selectively formed on the barrier layer 13, a metal material is deposited and a portion of the metal material deposited on the resist film is removed together with the resist film. Therefore, when the wall of the opening is inclined, the metal material can be easily deposited within the opening so as to improve adhesiveness of the ohmic electrode onto the wall of the opening.

FIG. 4 shows characteristics of drain currents and drain voltages against various bias voltages obtained in the HFET of this embodiment and a conventional HFET. As shown in FIG. 4, under any bias conditions, the on resistance is lower and the current value is larger in the HFET of this embodiment than in the conventional HFET.

### Embodiment 2

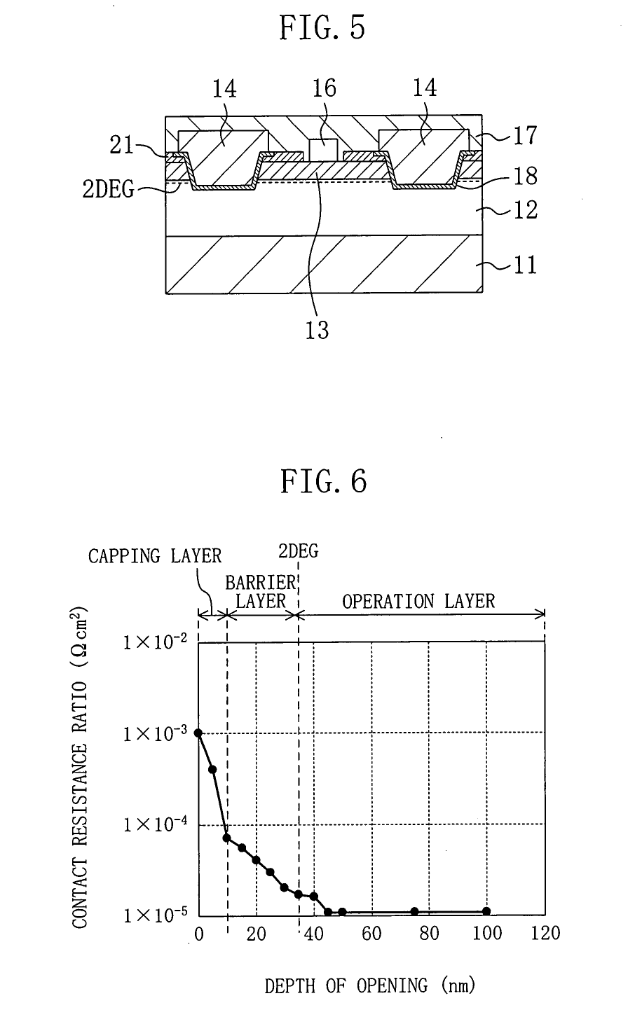

Embodiment 2 of the invention will now be described with reference to the accompanying drawings. FIG. 5 shows the cross-sectional structure of a semiconductor device according to Embodiment 2. In FIG. 5, like reference numerals are used to refer to like elements shown in FIG. 1 so as to omit the description.

As shown in FIG. 5, the semiconductor device of this embodiment includes a capping layer 21 formed on a barrier layer 13 and made of GaN or Al_{y}Ga_{(1-y)}N (wherein 0<y≦1). The capping layer 21 may have any conductivity type of n-type, p-type and i-type, and it is assumed in this embodiment that it has the p-type conductivity.

When the capping layer 21 has the p-type conductivity, an effect to suppress current collapse is particularly attained. In the case where an ohmic electrode 14 is formed so as to be in contact with the top face of the p-type capping layer 21, however, the contact resistance is largely increased.

In the HFET of this embodiment, each of ohmic electrodes 14 working as a source electrode and a drain electrode is formed by filling an opening formed so as to penetrate the capping layer 21 and the barrier layer 13 and trench an operation layer 12 down to a portion thereof disposed beneath a 2DEG layer. Furthermore, an impurity doped layer 18 doped with an n-type impurity such as silicon is formed on portions of the capping layer 21, the barrier layer 13 and the operation layer 12 in contact with the ohmic electrodes 14.

FIG. 6 shows the relationship between the depth of the opening and a contact resistance ratio. As shown in FIG. 6, in the case where the depth of the opening is 0 nm, namely, in the case where the ohmic electrode 14 is formed to be in contact with the top face of the capping layer 21, the resultant contact resistance ratio has a value of approximately 1×10⁻³. On the other hand, in the case where an opening with a depth of 15 nm reaching the interface between the capping layer 21 and the barrier layer 13 is formed and the ohmic electrode 14 is formed to be in contact with the top face of the barrier layer 13, the resultant contact resistance ratio is reduced to 1/10 and has a value of approximately 0.8×10⁻⁴. The contact resistance ratio is still reduced by further increasing the depth of the opening, and in the case where the opening is formed to be deeper than the 2DEG layer by approximately 10 nm, the resultant contact resistance ratio becomes substantially constant at a value of approximately 1×10⁻⁵.

In this manner, it is obvious that the contact resistance of an ohmic electrode can be largely reduced by forming an opening and forming the ohmic electrode in the opening. In this case, the opening is preferably formed to be deeper than the 2DEG layer by 10 nm or more so that the base of the ohmic electrode can reach a portion deeper than the 2DEG layer by 10 nm or more because the contact resistance can be thus further reduced. Also, when the opening is formed to be deeper than the 2DEG layer by 10 nm or more, the contact resistance is substantially constant, and hence, there is no need to strictly control the etching end point in forming the opening by the etching. Therefore, the semiconductor device can be easily fabricated.

In this manner, in the case where a capping layer is formed, the effect to reduce the contact resistance is particularly remarkable. The same effect can be attained not only when the capping layer has the p-type conductivity but also when it has the n-type conductivity or is undoped.

### Embodiment 3

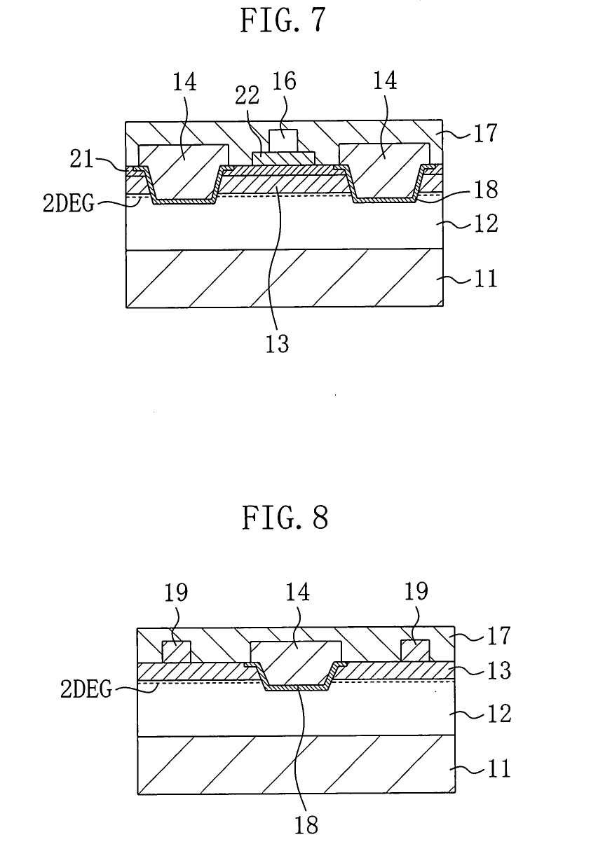

Embodiment 3 of the invention will now be described with reference to the accompanying drawing. FIG. 7 shows the cross-sectional structure of a semiconductor device according to Embodiment 3. In FIG. 7, like reference numerals are used to refer to like elements shown in FIG. 5 so as to omit the description.

As shown in FIG. 7, the semiconductor device of this embodiment includes a control layer 22 formed between a gate electrode 16 and a capping layer 21. The control layer 22 is made of p-type GaN or Al_{z}Ga_{(1-z)}N (wherein 0<z≦1) and is in ohmic contact with the gate electrode 16.

Since the control layer 22 has the p-type conductivity and is in ohmic contact with the gate electrode 16, a pn junction is formed between the control layer 22 and an operation layer 12. Therefore, even when no bias is applied to the gate electrode 16, a depletion layer is formed directly below the control layer 22. As a result, the HFET of this embodiment is a normally off (enhancement) type transistor while an HFET having a general Schottky contact gate electrode not using the control layer 22 is a normally on (depletion) type transistor. In a power supply circuit of a power system in particular, a normally off type transistor is indispensable as a switch, and the semiconductor device of this embodiment is useful in such a use.

### Embodiment 4

Embodiment 4 of the invention will now be described with reference to the accompanying drawings. FIG. 8 shows the cross-sectional structure of a semiconductor device according to Embodiment 4.

As shown in FIG. 8, the semiconductor device of this embodiment is a Schottky barrier diode (SBD). An operation layer 12 made of GaN and a barrier layer 13 made of AlₓGa₍₁₋ₓ₎N (wherein 0<x≦1) having a larger band gap than GaN are formed on a substrate 11. Since a heterojunction interface is formed between the operation layer 12 and the barrier layer 13, a 2DEG layer is generated in the vicinity of the heterojunction interface.

An ohmic electrode 14 corresponding to a cathode electrode is formed so as to penetrate the barrier layer 13 and to reach a portion of the operation layer 12 disposed beneath the 2DEG layer, and an anode electrode 19 corresponding to a Schottky electrode is formed so as to surround the ohmic electrode 14. A surface protection film 17 made of silicon nitride (SiN) is formed so as to cover the ohmic electrode 14 and the anode electrode 19.

Also in this embodiment, an impurity doped layer 18 doped with an n-type impurity is formed on portions of the barrier layer 13 and the operation layer 12 in contact with the ohmic electrode 14. Also, when the ohmic electrode 14 is formed so as to reach a portion deeper than the 2DEG layer by 10 nm or more, the contact resistance can be further reduced.

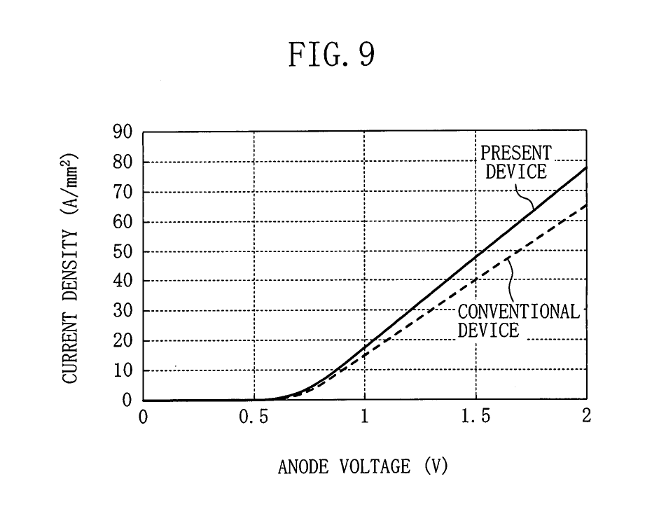

FIG. 9 shows the relationship between an anode voltage and a current density obtained in the SBD of this embodiment and a conventional SBD. As shown in FIG. 9, it is obvious that the current density is higher and the contact resistance is smaller in the SBD of this embodiment than in the conventional SBD.

Although each of the barrier layer, the capping layer and the control layer is made of a single film in each of the aforementioned embodiments, each of the barrier layer, the capping layer and the control layer may have a multilayered structure including a plurality of films stacked.

Each of the ohmic electrode and the Schottky electrode may be made of a general material, for example, an n-type ohmic electrode may be made of titanium (Ti), aluminum (Al) or a multilayered film of titanium (Ti) and aluminum (Al), a p-type ohmic electrode may be made of a multilayered film of nickel (Ni), platinum (Pt) and gold (Au), and a Schottky electrode may be made of a multilayered film of palladium (Pd) or alloy of palladium and silicon (PdSi) and gold (Au).

As described so far, according to the present invention, a semiconductor device using a group III-V nitride semiconductor including an ohmic electrode with small contact resistance can be realized, and the invention is useful as a semiconductor device or the like using a group III-V nitride semiconductor.

What is claimed is:

1. A semiconductor device comprising:
a first group III-V nitride semiconductor layer formed above a substrate and having a two-dimensional electron gas layer;
a second group III-V nitride semiconductor layer formed on said first group III-V nitride semiconductor layer and having a larger band gap than said first group Ill-V nitride semiconductor layer;
at least one ohmic electrode formed to have a base portion penetrating said second group III-V nitride semiconductor layer and reaching a portion of said first group III-V nitride semiconductor layer disposed beneath said two-dimensional electron gas layer; and
an impurity doped layer formed in portions of said first group III-V nitride semiconductor layer and said second group III-V nitride semiconductor layer in contact with said ohmic electrode, and doped with an impurity having conductivity.

2. The semiconductor device of claim 1,
wherein said second group III-V nitride semiconductor layer has a multilayered structure in which a plurality of group III-V nitride semiconductor layers are stacked.

3. The semiconductor device of claim 1,
wherein said ohmic electrode is two in number spaced from each other, and
a gate electrode is formed above said second group Ill-V nitride semiconductor layer to be disposed between said two ohmic electrodes.

4. The semiconductor device of claim 1, further comprising a third group III-V nitride semiconductor layer formed on said second group III-V nitride semiconductor layer,
wherein said ohmic electrode is formed to have at least a portion thereof penetrating said third group III-V nitride semiconductor layer.

5. The semiconductor device of claim 4,
wherein said third group III-V nitride semiconductor layer has a multilayered structure in which a plurality of group III-V nitride semiconductor layers are stacked.

6. The semiconductor device of claim 4,
wherein said ohmic electrode is two in number spaced from each other, and
a gate electrode is formed above said second group III-V nitride semiconductor layer to be disposed between said two ohmic electrodes.

7. The semiconductor device of claim 6,
wherein said third group III-V nitride semiconductor layer has, in a region disposed between said two ohmic electrodes, a gate recess for exposing said second group III-V nitride semiconductor layer therein, and
said gate electrode is formed in said gate recess.

8. The semiconductor device of claim 6, further comprising a fourth group III-V nitride semiconductor layer having a p-type conductivity and formed between said gate electrode and said third group III-V nitride semiconductor layer,
wherein said gate electrode is in ohmic contact with said fourth group III-V nitride semiconductor layer.

9. The semiconductor device of claim 1, further comprising an anode electrode formed above said second group III-V nitride semiconductor layer in a position different from said ohmic electrode and in Schottky contact with said second group III-V nitride semiconductor layer.

10. The semiconductor device of claim 1,
wherein said ohmic electrode is formed by filling an opening penetrating said second group III-V nitride semiconductor layer and reaching a portion of said first group Ill-V nitride semiconductor layer disposed beneath said two-dimensional electron gas layer, and
a wall of said opening is inclined to have a larger width in a higher portion thereof.

11. The semiconductor device of claim 1,
wherein said impurity having the conductivity is silicon.

12. The semiconductor device of claim 1,
wherein said base portion of said ohmic electrode is formed down to a portion of said first group III-V nitride semiconductor layer deeper than said two-dimensional electron gas layer by 10 nm or more.

13. The semiconductor device of claim 1,
wherein said ohmic electrode has an overhang portion overhanging a top face of said second group III-V nitride semiconductor layer, and
said overhang portion has a length of 1 μm or less.
